(19) United States
(12) Patent Application Publication
(10) Pub. No.: US 2017/0152597 A1
(43) Pub. Date: Jun. 1, 2017

(54) SUBSTRATE EVAPORATION-COATING DEVICE AND EVAPORATION-COATING METHOD

(71) Applicants: BOE TECHNOLOGY GROUP CO., LTD., Beijing (CN); ORDOS YUANSHENG OPTOLOELECTRONICS CO., LTD., Inner Mongolia (CN)

(72) Inventors: Qun MA, Beijing (CN); Yutai YUAN, Beijing (CN); Minhui JIA, Beijing (CN)

(21) Appl. No.: 14/434,718

(22) PCT Filed: Aug. 12, 2014
(86) PCT No.: PCT/CN2014/084186

§ 371 Date: Jan. 10, 2017

(30) Foreign Application Priority Data
Apr. 29, 2014 (CN) 201410177653.7

(51) Int. Cl. C23C 14/54; C03C 17/00; C23C 14/24

(52) U.S. Cl. CPC C23C 14/545; C23C 14/243; C03C 17/001

(57) ABSTRACT

The present disclosure relates to the field of the evaporation-coating, discloses a substrate evaporation-coating device and an evaporation-coating method. The evaporation-coating method comprises: pre-evaporation-coating the substrate; measuring the thickness distribution of the film layer after evaporation-coating; and dividing the film layer into several thickness areas according to the thickness distribution of the film layer; adjusting the distance between the evaporation source and the substrate; selecting the movement trajectory of the evaporation source according to the measured thickness distribution and adjusting the thickness of the film layer on the substrate by moving the evaporation source. The present disclosure is particularly suitable for spot evaporation source which can be changed from stationary to mobile, and the movement trajectory of the evaporation source can be selected based on the thickness distribution of the film layer. The spot evaporation source can move according to certain trajectory while evaporation-coating, so that the problem of un-uniform film thickness can be solved. Meanwhile, because the distance between the substrate and the evaporation source can be adjusted, the cycle time can be reduced and the utilization of the material can be increased by reducing the distance.

### RELATED APPLICATIONS

The present application claims the benefit of Chinese Patent Application No. 201410177653.7, filed on Apr. 29, 2014, the entire disclosure of which is incorporated herein by reference.

### FIELD OF THE INVENTION

The present disclosure relates to a field of an evaporation-coating, in particular to a substrate evaporation-coating device and an evaporation-coating method.

### BACKGROUND OF THE INVENTION

In the manufacturing of OLED (Organic Light-Emitting Diode) device, evaporation-coating is an important process. The OLED device needs photoelectric film layer (metal material) and organic film that are evaporation-coated on glass substrate.

Currently, the evaporation source can be classified into two kinds: spot evaporation source and linear evaporation source. Because the temperature required by the evaporation-coating of the cathode of the OLED device is high, the spot evaporation source is commonly used in the industry. As shown in FIG. 6, during the process of evaporation-coating, the evaporation source 1 is disposed in a casing 2 which is open in the upper portion. The glass substrate 3 is disposed over the evaporation source. The evaporation source 1 is stationary. According to the ion emission cosine law, if the glass substrate is relatively stationary, the film on the substrate after evaporation-coating by the spot evaporation source is thick in the middle and thin at the periphery; and if the glass substrate is moving during evaporation-coating, then the film after evaporation-coating might be thin in the middle, thick at the periphery or have an irregular thickness distribution.

To sum up, the film thickness of the glass substrate that is evaporation-coated by spot evaporation source has poor uniformity, which can significantly influence display effect.

### SUMMARY OF THE DISCLOSURE

The disclosure solves the problem of un-uniform film thickness of the glass substrate that is evaporation-coated by prior art spot evaporation source.

In order to solve the above technical problem, the present disclosure provides a substrate evaporation-coating device, comprising:

an evaporation source, which is used to evaporation-coat a substrate;

an X axis movement mechanism, which is used to realize the movement of the evaporation source in X-axis direction;

a Y axis movement mechanism, which is used to realize the movement of the evaporation source in Y-axis direction; and

a Z axis movement mechanism, which is used to realize the movement of is the evaporation source in Z-axis direction.

According to an aspect of the present disclosure, the substrate evaporation-coating device further comprises a controller, the controller is connected with the X axis movement mechanism, the Y axis movement mechanism and the Z axis movement mechanism respectively, and is used to control the position and the speed of the evaporation source along the X axis, the Y axis, and the Z axis.

According to an aspect of the present disclosure, the opening size of the injection port of the evaporation source can be adjusted.

According to another aspect of the present disclosure, the injection port is provided with a baffle. The lower end of the baffle can be rotatably connected with the rim of the injection port, and the baffle can move outward or inward relative to the central axis of the injection port to increase or decrease the opening of the injection port.

According to another aspect of the present disclosure, the baffle has a curved face shape that bends along the rim of the injection port.

According to a further aspect of the present disclosure, the baffle is a two-piece baffle, and the two pieces of the baffle are disposed at two opposite sides of the injection port and the two pieces are combined to form a flared mouth. During the process that the baffle moves outward or inward relative to the central axis of the injection port, the two pieces of the baffle can slide relative to each other.

The disclosure provides a substrate evaporation-coating method, comprising:

pre-evaporation-coating the substrate and measuring the thickness distribution of the film layer after evaporation-coating, and dividing the film layer into several thickness areas according to the thickness distribution of the film layer;

adjusting the distance between the evaporation source and the substrate;

selecting movement trajectory of the evaporation source according to the measured thickness distribution, and adjusting the thickness of the film layer on the substrate by moving the evaporation source. If the distribution of the is film layer on the substrate is thick in the middle and thin at the periphery, the movement trajectory of the evaporation source along X axis and Y axis can be controlled to make circular motion. If the distribution of the film layer on the substrate is thin in the middle and thick at the periphery, the movement trajectory of the evaporation source along X axis and Y axis can be controlled to make rectilinear motion or S shaped curvilinear motion. If the distribution of the film layer on the substrate is irregular, the movement trajectory of the evaporation source along X axis and Y axis can be controlled to make the combination of circular motion and rectilinear motion.

According to an aspect of the present disclosure, the opening size of the injection port of the evaporation source can be adjusted during the movement of the evaporation source.

According to an aspect of the present disclosure, if the movement of the evaporation source cannot improve the thickness distribution of the film layer on the substrate, the evaporation source can be controlled to move in Z axis to adjust the distance between the evaporation source and the substrate.

The substrate evaporation-coating device and the evaporation-coating method provided in the present disclosure is particularly suitable to spot evaporation source which is changed from stationary to mobile, and the movement trajectory of the evaporation source can be selected based on the thickness distribution of the film layer. The spot evaporation source can move according to certain trajectory during evaporation-coating, so that the problem of un-uniform film thickness can be solved. Meanwhile, because the distance between the substrate and the evaporation source can be adjusted, the cycle time can be reduced and the utilization of the material can be increased by reducing the distance.

### BRIEF DESCRIPTION OF THE DRAWINGS

FIG. 1 is an exploded view of an evaporation-coating device according to the present disclosure.

FIG. 2 is a schematic view showing the structure of an evaporation source according to the present disclosure;

FIG. 3 is a schematic program showing the working principle according to a first evaporation-coating method;

FIG. 4 is a schematic program showing the working principle according to a second evaporation-coating method;

FIG. 5 is a schematic program showing the working principle according to a third evaporation-coating method;

FIG. 6 is a schematic program showing the evaporation-coating of the prior art evaporation-coating source.

### DETAILED DESCRIPTION OF THE INVENTION

The specific embodiments of the present disclosure will be further described in more detail in conjunction with the attached drawings. The following embodiments are used to illustrate the present disclosure and not to limit the scope of the present disclosure.

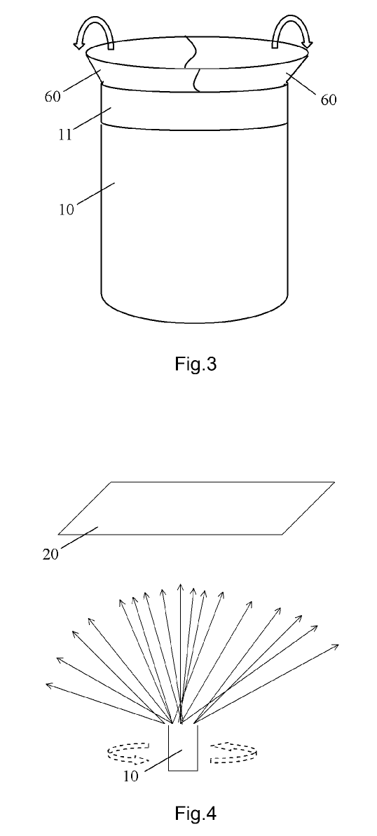

As shown in FIGS. 1 and 3, a substrate evaporation-coating device according to the disclosure comprises an evaporation source 10, an X axis movement mechanism, a Y axis movement mechanism and a Z axis movement mechanism. Wherein, the evaporation source 10 is used to evaporation-coat a substrate 20; the X axis movement mechanism is used to realize movement of the evaporation-source in the X axis direction; the Y axis movement mechanism is used to realize movement of the evaporation-source in the X axis direction; and the Z axis movement mechanism is used to realize movement of the evaporation-source in the Z axis direction.

The substrate evaporation-coating device further comprises a controller; the controller is connected with the X axis movement mechanism, the Y axis movement mechanism and the Z axis movement mechanism, and is used to control the position and speed of the evaporation source along the X axis, the Y axis, and the Z axis.

Preferably, the X axis movement mechanism comprises: an X axis slider 31, an X axis guide rail 32 and an X axis drive motor disposed on the X axis slider 31 respectively. The Y axis movement mechanism comprises a Y axis slider 41, a Y axis guide rail 42 and a Y axis drive motor disposed on the Y axis slider 41 respectively. The Z axis movement mechanism comprises a Z axis slider 51, a Z axis guide rail 42 and a Z axis drive motor disposed on the Z axis slider 51 respectively. The evaporation source 10 can be movably mounted on the Z axis guide rail 52. The Z axis slider 51 is movably mounted on the X axis guide rail 32. The X axis slider 31 is movably mounted on the Y axis guide rail 42. Wherein the Z axis drive motor can be connected with the evaporation source 10 through Z axis drive mechanism so as to drive the evaporation source to move along the Z axis guide rail in Z axis direction; the X axis drive motor can be connected with the Z axis slider 51 through X axis drive mechanism, so as to drive the Z axis slider 51 together with the evaporation source mounted thereon to move along the X axis guide rail 32 in X axis direction; the Y axis drive motor can be connected with the X axis slider 31 through the Y axis drive mechanism, so as to drive the X axis slider 31 together with the Z axis slider 51 mounted on the X axis slider 31 and the evaporation source 10 to move along the Y axis guide rail 42 in Y axis direction. Wherein, the X axis drive mechanism, the Y axis drive mechanism and the Z axis drive mechanism can be realized by employing multi-gear drive mechanism or gear-rack drive mechanism or the like. The X axis, Y axis or Z axis drive motors can be stepper motors.

It should be noted that the X axis movement mechanism, the Y axis movement mechanism and the Z axis movement mechanism can be other structures, as long as they can realize the movement of the evaporation source along the X axis, Y axis and Z axis.

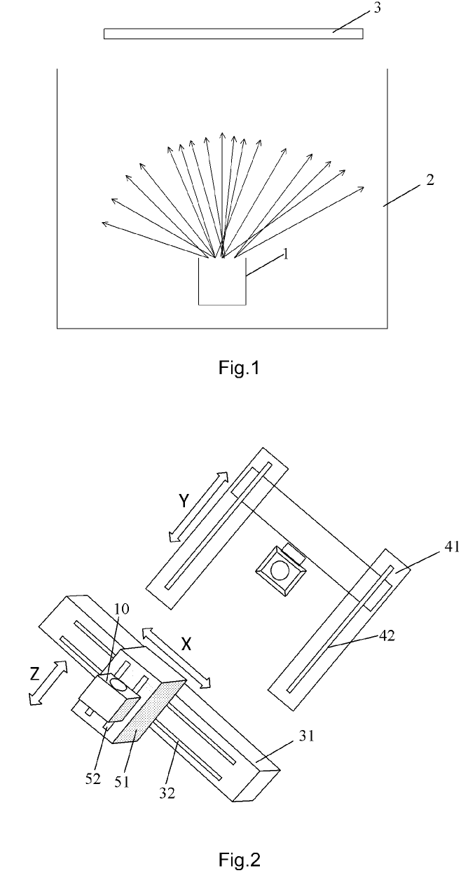

As shown in FIG. 2, the opening size of the injection port 11 of the evaporation source 10 can be adjusted. Preferably, the opening size of the injection port 11 can be adjusted in the following way: a baffle 60 is disposed at the injection port 11; the lower end of the baffle 60 can be rotatably connected with the rim of the injection port 11, and the baffle 60 can move outward or inward relative to the central axis of the injection port 11 to increase or decrease the opening of the injection port 11. When the baffle 60 moves inwards relative to the central axis of the injection port 11, the opening of the injection port 11 can be decreased. When the baffle 60 moves outwards is relative to the central axis of the injection port 11, as shown by the arrow in FIG. 2, the opening of the injection port 11 can be increased. The bigger the opening size of the injection port 11, the larger the port's injecting area is. The outward movement or inward movement of the baffle 60 relative to the central axis of the injection port 11 can be realized by means of hinge mechanism and/or sliding guide rail mechanism and the like. The injection direction of the injection port 11 can be e.g. perpendicular to the substrate. Or alternatively, a certain angle can be included between the injection direction of the injection port 11 and the substrate 3 so as to adjust the evaporation-coating thickness.

Preferably, the baffle can have curved face shape that bends along the rim of the injection port. Comparing to a square baffle, on one hand, this can better control the direction and shape of the vapor evaporation-coating so that the injection can be more uniform during evaporation-coating. On the other hand, the curved face shape can facilitate the installing of the baffle above the evaporation source. Furthermore, with a square baffle, the film might have sharp distinct areas on the substrate after evaporation-coating, and film thickness has poor uniformity. With curved face baffle (flared type), the vapor can be emitted in flared shape, and experiments prove that the uniformity of the film thickness can be better in this way.

In order to conveniently adjust the opening size of the injection port, the baffle 60 is a two-piece baffle, and the two pieces of the baffle are disposed at two opposite sides of the injection port 11 and the two pieces 60 are combined to form a flared mouth, as shown in FIG. 2. During the process that the baffle moves outward or inward relative to the central axis of the injection port, the two pieces of the baffle 60 can slide relative to each other by means of a sliding mechanism. Once the positions of the two pieces of the baffle 60 have been adjusted, the two pieces of baffle can be secured by means of insert connectors or snap joints. Such insert connectors or snap joints can be provided on the baffle. There are several adjusting points, which are adapted to secure baffles for different injection ports with different opening sizes.

The present disclosure further provides an evaporation-coating method by means of the substrate evaporation-coating device according to the above technical solution. The method comprises:

S1, pre-evaporation-coating the substrate and measuring the thickness distribution of the film layer after evaporation-coating, and dividing the film layer into several thickness areas according to the thickness distribution of the film layer and identifying them. As to spot evaporation source, the thickness distribution of the film layer produced by it can be classified into the following three situations: thick in middle; thin in periphery; thin in the middle and thick periphery; and irregular.

S2, adjusting the distance between the evaporation source and the substrate, wherein, in the case that the opening size of the injection port of the evaporation source can be adjusted, the opening size of the injection port of the evaporation source can be adjusted while evaporation-coating. Specifically: the suitable distance between the evaporation source and the substrate can be adjusted by controlling the movement of the evaporation source along the Z axis guide rail in the Z axis direction. The distance can be obtained through experiments. Experiments prove that the best distance for best thickness uniformity of the film is generally about 400-800 mm; the opening size of the injection port 11 can be adjusted by means of the baffles and the opening size can be 5-30 mm.

S3, selecting movement trajectory of the evaporation source according to the measured thickness distribution, and adjusting the thickness of the film layer on the substrate by moving the evaporation source.

Specifically, the movement trajectories of the evaporation source can be preset in the controller; a certain movement trajectory of the evaporation source can be selected according to the thickness distribution of the film layer measured in step S1; and the thickness of the film layer on the substrate can be adjusted by controlling the movement trajectory of the evaporation source. The following are most commonly used solutions.

If the distribution of the film layer on the substrate 20 is thick in the middle and thin at the periphery, the evaporation source 10 can be controlled by the controller to make circular motion along the X axis and the Y axis, but remain stationary in the Z direction. That is, the movement trajectory of the evaporation source 20 along the x axis and Y axis can be adjusted by setting proper X, Y coordinates so that the evaporation source 10 can make circular motion (as shown by the arrow in FIG. 3) at the periphery where the film layer is thin, in order to compensate the area with insufficient thickness, so that the substrate 20 can have uniform film thickness, as shown in FIG. 3.

If the distribution of the film layer on the substrate 20 is thin in the middle and thick at the periphery, the evaporation source 10 can be controlled by the controller to make rectilinear motion along the X axis and the Y axis, but remain stationary in the Z direction so that the evaporation source 10 can make rectilinear motion (as shown by the arrow in FIG. 4) or S shaped curvilinear motion at the periphery where the film layer is thin, in order to compensate the area with insufficient thickness, so that the substrate 20 can have uniform film thickness, as shown in FIG. 4.

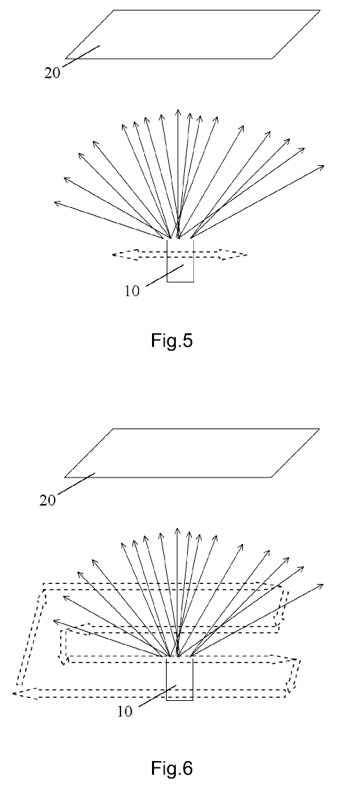

If the film layer has irregular distribution on the substrate 20, the evaporation source 10 can be controlled by the controller to make the combination of circular motion and rectilinear motion along the X axis and the Y axis. The evaporation source 10 can make circular motion or rectilinear motion or S shaped curvilinear motion (as shown by the arrow direction in FIG. 5) as required. During this process, it remains stationary in the Z axis direction, as shown in FIG. 5.

In the course of the movement of the above mentioned evaporation source, the opening size of the injection port of the evaporation source can be adjusted at the same time. The adjusting of the opening size of the injection port of the evaporation source and the adjusting of the movement trajectory can be combined so as to realize the film thickness uniformity of the evaporation-coating.

If the movement of the evaporation source cannot improve the thickness distribution of the film layer on the substrate, the movement of the evaporation source in Z axis can be controlled to adjust the distance between the evaporation source and the substrate, thereby to reduce the cycle time of the evaporation-coating and increase the utilization of the materials.

The substrate evaporation-coating device and the evaporation-coating method in the disclosure are particularly suitable for spot evaporation source. The evaporation source is changed from stationary to mobile, and its movement trajectory can be selected according to the thickness distribution of the film layer. The spot evaporation source can move according to certain trajectory while evaporation-coating, so that the problem of un-uniform film thickness due to ion emission cosine law can be solved. Meanwhile, because the distance between the substrate and the evaporation source can be flexibly adjusted, the cycle time can be reduced and the utilization of the material can be increased.

The above description is only preferred embodiments of the present disclosure. It should be noted that various modifications and replacement can be made without departing from the technical principle of the present disclosure. Those modifications and replacement should be construed as within the protection scope of the present disclosure.

1. A substrate evaporation-coating device, comprising:
an evaporation source for evaporation-coating a substrate;
an X axis movement mechanism, which is used to realize the movement of the evaporation source in X-axis direction;
a Y axis movement mechanism, which is used to realize the movement of the evaporation source in Y-axis direction; and
a Z axis movement mechanism, which is used to realize the movement of the evaporation source in Z-axis direction.

2. The substrate evaporation-coating device according to claim 1, further comprising a controller, the controller is connected with the X axis movement mechanism, the Y axis movement mechanism and the Z axis movement mechanism respectively, and is used to control the position and the speed of the evaporation source along the X axis, the Y axis, and the Z axis.

3. The substrate evaporation-coating device according to claim 1, wherein the opening size of the injection port of the evaporation source can be adjusted.

4. The substrate evaporation-coating device according to claim 3, wherein the injection port is provided with a baffle; the lower end of baffle is rotatably connected with the rim of the injection port; and the baffle can move outward or inward relative to the central axis of the injection port to increase or decrease the opening of the injection port.

5. The substrate evaporation-coating device according to claim 4, wherein the baffle has a curved face shape that bends along the rim of the injection port.

6. The substrate evaporation-coating device according to claim 4, wherein the baffle is a two-piece baffle; the two pieces of the baffle are disposed at two opposite sides of the injection port and the two pieces are combined to form a flared mouth; during the process that the baffle moves outward or inward relative to the central axis of the injection port, the two pieces of the baffle can slide relative to each other.

7. The substrate evaporation-coating device according to claim 5, wherein the baffle is a two-piece baffle; the two pieces of the baffle are disposed at two opposite sides of the injection port and the two pieces are combined to form a flared mouth; during the process that the baffle moves outward or inward relative to the central axis of the injection port, the two pieces of the baffle can slide relative to each other.

8. A substrate evaporation-coating method, comprising:
pre-evaporation-coating the substrate and measuring the thickness distribution of the film layer after evaporation-coating, and dividing the film layer into several thickness areas according to the thickness distribution of the film layer;
adjusting the distance between the evaporation source and the substrate;
selecting movement trajectory of the evaporation source according to the measured thickness distribution of the film layer, and adjusting the thickness of the film layer on the substrate by moving the evaporation source.

9. The substrate evaporation-coating method according to claim 8, wherein, selecting movement trajectory of the evaporation source according to the measured thickness distribution of the film layer and adjusting the thickness of the film layer on the substrate by moving the evaporation source comprises: if the distribution of the film layer on the substrate is thick in the middle and thin at the periphery, the movement trajectory of the evaporation source along X axis and Y axis is controlled to make circular motion.

10. The substrate evaporation-coating method according to claim 8, wherein, selecting movement trajectory of the evaporation source according to the measured thickness distribution of the film layer and adjusting the thickness of the film layer on the substrate by moving the evaporation source comprises: if the distribution of the film layer on the substrate is thin in the middle and thick at the periphery, the movement trajectory of the evaporation source along X axis and Y axis can be controlled to make rectilinear motion or S shaped curvilinear motion.

11. The substrate evaporation-coating method according to claim 8, wherein, selecting movement trajectory of the evaporation source according to the measured thickness distribution of the film layer and adjusting the thickness of the film layer on the substrate by moving the evaporation source comprises: if the distribution of the film layer on the substrate is irregular, the movement trajectory of the evaporation source along X axis and Y axis can be controlled to make the combination of circular motion and rectilinear motion.

12. The substrate evaporation-coating method according to claim 8, wherein, during the movement of the evaporation source, the opening size of the injection port of the evaporation source can be adjusted.

13. The substrate evaporation-coating method according to claim 9, wherein, during the movement of the evaporation source, the opening size of the injection port of the evaporation source can be adjusted.

14. The substrate evaporation-coating method according to claim 10, wherein, during the movement of the evaporation source, the opening size of the injection port of the evaporation source can be adjusted.

15. The substrate evaporation-coating method according to claim 11, wherein, during the movement of the evaporation source, the opening size of the injection port of the evaporation source can be adjusted.

16. The substrate evaporation-coating method according to claim 8, wherein, if the movement of the evaporation source cannot improve the thickness distribution of the film layer on the substrate, the movement of the evaporation source in Z axis can be controlled to adjust the distance between the evaporation source and the substrate.

17. The substrate evaporation-coating method according to claim 9, wherein, if the movement of the evaporation source cannot improve the thickness distribution of the film layer on the substrate, the movement of the evaporation source in Z axis can be controlled to adjust the distance between the evaporation source and the substrate.

18. The substrate evaporation-coating method according to claim 10, wherein, if the movement of the evaporation source cannot improve the thickness distribution of the film layer on the substrate, the movement of the evaporation source in Z axis can be controlled to adjust the distance between the evaporation source and the substrate.

19. The substrate evaporation-coating method according to claim 11, wherein, if the movement of the evaporation source cannot improve the thickness distribution of the film layer on the substrate, the movement of the evaporation source in Z axis can be controlled to adjust the distance between the evaporation source and the substrate.
